(19) United States
(12) Patent Application Publication
(10) Pub. No.: US 2026/0324313 A1
(43) Pub. Date: Oct. 15, 2026

(54) SEMICONDUCTOR DEVICE AND METHOD OF FABRICATING SEMICONDUCTOR DEVICE

(71) Applicant: SK hynix Inc., Gyeonggi-do (KR)

(72) Inventors: Mohammad Taghi Sharbati, San Jose, CA (US); Agus Sofian Tjandra, San Jose, CA (US); Dengtao Zhao, San Jose, CA (US); Sung-Taeg Kang, San Jose, CA (US)

(21) Appl. No.: 19/174,922

(22) Filed: Apr. 10, 2025

(51) Int. Cl. H01L 21/02

(52) U.S. Cl. CPC H10P 14/6529; H10P 14/69215; H10P 14/69433

(57) ABSTRACT

There is provided a semiconductor device and a method of fabricating a semiconductor device capable of securing efficient passivation by introducing multi-cycle passivation including an additional fresh nitride passivation layer and subsequent passivation anneal. The method may include forming a first passivation layer over a substrate; performing a first anneal on the first passivation layer; removing an upper part of the first passivation layer; forming a second passivation layer on a remaining first passivation layer; and performing a second anneal on the second passivation layer and the remaining first passivation layer.

### BACKGROUND

### 1. Technical Field

Embodiments of the present disclosure relate to a semiconductor device and a method of fabricating a semiconductor device.

### 2. Related Art

In semiconductor manufacturing, “passivation” generally refers to the process of applying a protective layer to the surface of a semiconductor device to reduce its chemical reactivity and electrical surface states, essentially making it less susceptible to environmental damage and improving the performance of the semiconductor device by minimizing unwanted interactions with the surrounding environment.

Passivation anneal is performed to passivate defects and active traps in a film such as a polysilicon layer, an oxide layer, a nitride layer, and the like during the semiconductor manufacturing. This technique effectively improves the electrical efficiency by reducing the trap sites (e.g., dangling bonds, oxygen vacancies).

Particularly, in three-dimensional (3D) NAND technology, electrical characteristics such as short term data retention (STDR), random telegraph noise (RTN), and string current may be impacted by the trap sites. The passivation anneal helps improving the electrical characteristics, increasing the total read window budget (RWB) which is critical for the higher cell level (e.g., QLC or PLC) and the next generation high density cell structures. Despite being a common technique, researchers at academia and industry are trying to explore the feasibility of a novel approach.

In this context, embodiments of the present disclosure arise.

### SUMMARY

Embodiments of the present disclosure are directed to a semiconductor device and a method of fabricating a semiconductor device capable of securing efficient passivation by introducing multi-cycle passivation including an additional fresh nitride passivation layer and subsequent passivation anneal.

In accordance with an embodiment of the present disclosure, there is provided a method of fabricating a semiconductor device. The method may include forming a first passivation layer over a substrate; performing a first anneal on the first passivation layer; removing an upper part of the first passivation layer; forming a second passivation layer on a remaining first passivation layer; and performing a second anneal on the second passivation layer and the remaining first passivation layer.

In an embodiment, each of the first anneal and the second anneal may be performed by using hydrogen-based anneal.

In an embodiment, each of the first passivation layer and the second passivation layer may include a nitride layer or an oxide layer.

In accordance with an embodiment of the present disclosure, there is provided a semiconductor device. The semiconductor device may include a substrate including a cell stack structure; a first hydrogen-based annealed passivation layer disposed over the substrate; and a second hydrogen-based annealed passivation layer disposed on the first hydrogen-based annealed passivation layer.

In an embodiment, the first hydrogen-based annealed passivation layer includes a nitride layer or an oxide layer.

In an embodiment, the second hydrogen-based annealed passivation layer includes a nitride layer or an oxide layer.

These and other features and advantages of the embodiments of the present disclosure will become apparent to those skilled in the art from the following detailed description in conjunction with the following drawings.

### BRIEF DESCRIPTION OF THE DRAWINGS

FIGS. 1 to 5 are cross-sectional view illustrating a fabrication processes of a semiconductor device in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and scope of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the principles and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

As used herein, singular forms are intended to include the plural forms as well, unless the context clearly indicates otherwise.

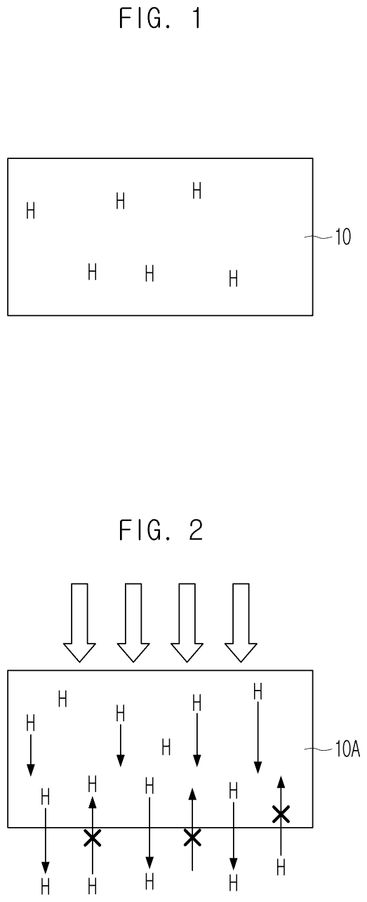

FIGS. 1 to 5 are cross-sectional view illustrating a fabrication processes of a semiconductor device in accordance with an embodiment of the present disclosure.

Referring to FIG. 1, a first passivation layer 10 may be formed over a substrate (not illustrated). The substrate may include a cell stack structure.

The first passivation layer 10 may include a nitride layer (e.g., SiN) or an oxide layer (e.g., SiO₂). For example, the first passivation layer 10 may be formed to have a thickness of 300 nm to 1000 nm.

Referring to FIG. 2, first passivation anneal may be performed on the first passivation layer 10. As a result of the first passivation anneal, the annealed first passivation layer 10A may be formed.

As atmosphere gas, forming gas (e.g., N₂/H₂, N₂/D₂), deuterium gas (D₂), hydrogen gas (H₂), or the like may be used for the first passivation anneal. Inert gas such as nitrogen gas (N₂) also may be used as the atmosphere gas. In an embodiment, the first passivation anneal may be performed under the condition with a temperature range of 400 °C to 500 °C and a pressure range of 1 atm to 20 atm.

Further, high pressure anneal (HPA), inductively coupled plasma (ICP) based hydrogen radical anneal, low energy plasma hydrogen doping (PLAD), laser anneal, or milli-second anneal may be performed as the first passivation anneal.

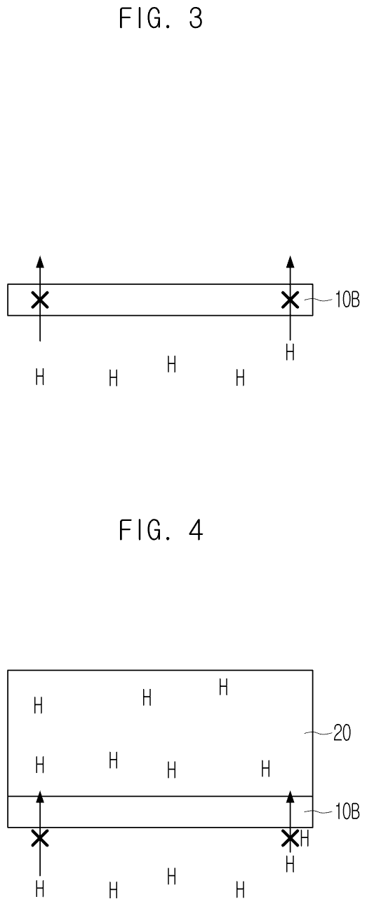

Referring to FIG. 3, an upper part of the annealed first passivation layer 10A may be removed. For example, the remaining first passivation layer 10B may have a thickness of 50 nm to 100 nm. In order to partially remove the annealed first passivation layer 10A, an etch back process or a chemical mechanical planarization (CMP) may be performed.

Referring to FIG. 4, a second passivation layer 20 may be formed on the remaining first passivation layer 10B. The second passivation layer 20 may include a nitride layer (e.g., SiN) or an oxide layer (e.g., SiO₂). For example, the second passivation layer 20 may be formed to have a thickness of 300 nm to 1000 nm.

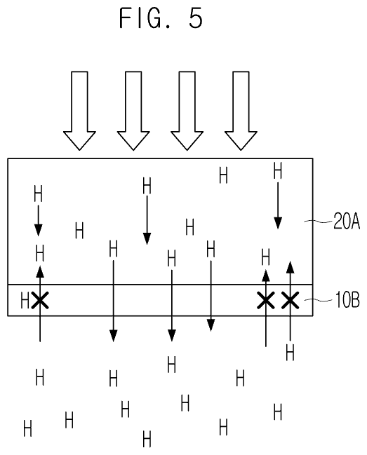

Referring to FIG. 5, second passivation anneal may be performed on the second passivation layer 20. As a result of the first passivation anneal, the annealed first passivation layer 20A may be formed.

As atmosphere gas, forming gas (e.g., N₂/H₂, N₂/D₂), deuterium gas (D₂), hydrogen gas (H₂), or the like may be used for the second passivation anneal. Inert gas such as nitrogen gas (N₂) also may be used as the atmosphere gas. In an embodiment, the second passivation anneal may be performed under the condition with a temperature range of 400 °C to 500 °C and a pressure range of 1 atm to 20 atm.

Further, high pressure anneal (HPA), inductively coupled plasma (ICP) based hydrogen radical anneal, low energy plasma hydrogen doping (PLAD), laser anneal, or milli-second anneal may be performed as the second passivation anneal.

The finalized passivation structure may be formed of the remaining first passivation layer 10B and the annealed second passivation layer 20A. The annealed second passivation layer 20A may serve as a hydrogen (H) reservoir. Further, the remaining first passivation layer 10B may serve as a hydrogen reservoir, and block hydrogen escaping from the cell stack structure.

The processes described in the above may vary according to embodiments of the present disclosure. For example, while two passivation cycles each including both passivation layer deposition and hydrogen-based anneal are applied to the above embodiment of the present disclosure, the number of passivation cycles may be 3 or more, and are critical for the effectiveness of the trap passivation, which depends on the hydrogen concentration diffused into the cell stack structure.

In accordance with the embodiment of the present disclosure, the multi-cycle passivation is proposed instead of the conventional single-step passivation. The multi-cycle passivation can significantly increase the passivation efficiency through the improved trap passivation at the cell stack structure. Further, the additional fresh passivation layer and the subsequent passivation anneal enables blocking hydrogen diffused and de-gassed out from the cell stack structure, thereby securing efficient passivation of the cell stack structure. This is more beneficial particularly when a specific thickness of the final passivation layer must remain consistent to minimize changes during process integration.

Referring again to FIG. 5, a semiconductor device in accordance with an embodiment of the present disclosure may include a substrate including a cell stack structure, a first hydrogen-based annealed passivation layer (i.e., 10B) disposed over the substrate, and a second hydrogen-based annealed passivation layer disposed on the first hydrogen-based annealed passivation layer (i.e., 20A).

In accordance with the embodiment of the present disclosure, the multi-layered passivation can significantly increase the passivation efficiency, thereby securing efficient passivation of the cell stack structure.

While the embodiments of the present disclosure describe a case where the multi-cycle passivation is applied to the cell stack structure, a target structure to be passivated may vary depending on a device design.

Further, while the embodiments of the present disclosure contain many specifics, these should not be construed as limitations on the scope of the present disclosure or of what may be claimed, but rather as descriptions of features that may be specific to particular embodiments of the present disclosure. Certain features that are described in the context of separate embodiments can also be implemented in combination to form a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few implementations and embodiments are described and other implementations, embodiments, enhancements and variations can be made based on what is described and illustrated in the present disclosure. Furthermore, the embodiments may be combined to form additional embodiments.

1. A method of fabricating a semiconductor device, the method comprising:
forming a first passivation layer over a substrate;
performing a first anneal on the first passivation layer;
removing an upper part of the first passivation layer;
forming a second passivation layer on a remaining first passivation layer; and
performing a second anneal on the second passivation layer and the remaining first passivation layer.

2. The method of claim 1, wherein the first passivation layer includes a nitride layer or an oxide layer.

3. The method of claim 2, wherein the second passivation layer includes a nitride layer or an oxide layer.

4. The method of claim 1, wherein each of the first anneal and the second anneal is performed by using hydrogen-based anneal.

5. The method of claim 4, wherein the hydrogen-based anneal is performed using hydrogen gas(H₂) or hydrogen-Atty nitrogen gas mixture(H₂/N₂) as an atmosphere gas.

6. The method of claim 4, wherein the hydrogen-based anneal is performed under a temperature ranging from 400 °C to 500 °C.

7. The method of claim 5, wherein the hydrogen-based anneal is performed under a pressure ranging from 1 atm to 20 atm.

8. The method of claim 4, wherein the hydrogen-based anneal is performed by high pressure anneal (HPA), inductively coupled plasma (ICP) based hydrogen radical anneal, a low energy plasma hydrogen doping (PLAD), a laser anneal, or a milli-second anneal.

9. The method of claim 4. wherein the hydrogen-based anneal is performed using nitrogen gas (N₂) as an inert gas.

10. The method of claim 1, wherein the first passivation layer is formed to have a thickness of 300 nm to 1000 nm.

11. The method of claim 10, wherein the remaining first passivation layer has a thickness of 50 nm to 100 nm.

12. The method of claim 1, wherein the second passivation layer is formed to have a thickness of 300 nm to 1000 nm.

13. The method of claim 1, wherein the substrate includes a cell stack structure.

14. A semiconductor device comprising:
a substrate including a cell stack structure;
a first hydrogen-based annealed passivation layer disposed over the substrate; and
a second hydrogen-based annealed passivation layer disposed on the first hydrogen-based annealed passivation layer.

15. The semiconductor device of claim 14, wherein the first hydrogen-based annealed passivation layer includes a nitride layer or an oxide layer.

16. The semiconductor device of claim 15, wherein the second hydrogen-based annealed passivation layer includes a nitride layer or an oxide layer.

17. The semiconductor device of claim 14, wherein the first hydrogen-based annealed passivation layer has a thickness of 50 nm to 100 nm.

18. The semiconductor device of claim 14, wherein the second hydrogen-based annealed passivation layer has a thickness of 300 nm to 1000 nm.

19. The method of claim 4, wherein the hydrogen-based anneal is performed (H₂) using deuterium gas (D₂) or deuterium-nitrogen gas mixture(D₂/N₂) as an atmosphere gas.
